(19) United States
(12) Patent Application Publication
(10) Pub. No.: US 2026/0191118 A1
(43) Pub. Date: Jul. 2, 2026

(54) SEMICONDUCTOR PACKAGE INCLUDING SOLDER BALL STRUCTURE

(71) Applicant: Samsung Electronics Co., Ltd., Suwon-si (KR)

(72) Inventors: Dongwoo SHIN, Suwon-si (KR); Jaehoon CHOI, Suwon-si (KR); Kwangho CHUN, Suwon-si (KR)

(73) Assignee: Samsung Electronics Co., Ltd., Suwon-si (KR)

(21) Appl. No.: 19/411,783

(22) Filed: Dec. 8, 2025

(30) Foreign Application Priority Data
Dec. 31, 2024 (KR) 10-2024-0201941

(51) Int. Cl. H10W 90/00; H10W 70/05; H10W 70/66

(52) U.S. Cl. CPC H10W 90/7295; H10W 70/093; H10W 70/66; H10W 90/724

(57) ABSTRACT

A semiconductor package includes a package substrate, a semiconductor chip on a first surface of the package substrate, a molding member on the first surface of the package substrate and covering the semiconductor chip, and solder ball structures on a second surface of the package substrate, the second surface of the package substrate being opposite the first surface of the package substrate, each of the solder ball structures including a first solder ball and a second solder ball, wherein the first solder ball has a first melting temperature and contacts a lower substrate pad on the second surface of the package substrate, and wherein the second solder ball has a second melting temperature lower than the first melting temperature and contacts at least a portion of a surface of the first solder ball.

### CROSS-REFERENCE TO RELATED APPLICATION

This application claims priority under 35 USC § 119 to Korean Patent Application No. 10-2024-0201941, filed on Dec. 31, 2024, in the Korean Intellectual Property Office (KIPO), the contents of which are incorporated by reference herein in their entirety.

### BACKGROUND

Various example embodiments relate to semiconductor packages. Particularly, various example embodiments relate to semiconductor packages including a solder ball structure used as an external connection member.

A solder ball, which is an external connection member of a semiconductor package, may be mounted and soldered on a circuit board. In general, in order to bond the solder ball and the circuit board, a process of applying heat at a melting temperature of the solder ball or a temperature higher than the melting temperature may be performed on the solder ball. However, in some cases, the solder ball and the circuit board may need to be bonded at a temperature lower than the melting temperature of the solder ball, and thus a bonding failure may easily occur.

### SUMMARY

Some example embodiments provide semiconductor packages including a solder ball structure.

Some example embodiments provide semiconductor modules having a semiconductor package including a solder ball structure.

According to an example embodiment, a semiconductor package includes a package substrate, a semiconductor chip on a first surface of the package substrate, a molding member on the first surface of the package substrate and covering the semiconductor chip, and solder ball structures on a second surface of the package substrate, the second surface of the package substrate being opposite the first surface of the package substrate, each of the solder ball structures including a first solder ball and a second solder ball, wherein the first solder ball has a first melting temperature and contacts a lower substrate pad on the second surface of the package substrate, and wherein the second solder ball has a second melting temperature lower than the first melting temperature and contacts at least a portion of a surface of the first solder ball.

According to an example embodiment, a semiconductor package module includes a package substrate, a semiconductor chip on a first surface of the package substrate, a molding member on the first surface of the package substrate and covering the semiconductor chip, a solder ball structure on a second surface of the package substrate, the second surface of the package substrate being opposite the first surface of the package substrate, the solder ball structure including a first solder ball and a second solder ball, the first solder ball having a first melting temperature and contacting a lower substrate pad on the second surface of the package substrate, the second solder ball having a second melting temperature lower than the first melting temperature, the second solder ball covering at least a portion of a surface of the first solder ball, a circuit board including an upper pad pattern, and a solder paste interposed between the upper pad pattern and the second solder ball of the solder ball structure and bonding the circuit board and the solder ball structure.

According to an example embodiment, a semiconductor package includes a package substrate, a semiconductor chip on a first surface of the package substrate, a molding member on the first surface of the package substrate and covering the semiconductor chip, a first solder ball having a first melting temperature, the first solder ball being on a second surface of the package substrate, the second surface of the package substrate being opposite the first surface of the package substrate, and a second solder ball bonded on at least a portion of a surface of the first solder ball, the second solder ball including a first solder paste, the second solder ball having a second melting temperature lower than the first melting temperature.

In some example embodiments, the first solder ball may include at least tin (Sn) and silver (Ag), and may not include bismuth (Bi) and indium (In).

In some example embodiments, the first solder ball may include a tin-silver (Sn-Ag) compound, a tin-silver-copper (Sn-Ag-Cu) compound, a tin-silver-copper-nickel (Sn-Ag-Cu-Ni) compound, a tin-silver-copper-antimony (Sn-Ag-Cu-Sb) compound, or a tin-silver-copper-germanium (Sn-Ag-Cu-Ge) compound.

In some example embodiments, the first solder paste may be a compound including tin (Sn) and at least one of bismuth (Bi) or indium.

In some example embodiments, the first solder paste may include a tin-bismuth (Sn-Bi) compound, a tin-bismuth-silver (Sn-Bi-Ag) compound, a tin-bismuth-copper (Sn-Bi-Cu) compound, a tin-bismuth-silver-copper (Sn-Bi-Ag-Cu) compound, a tin-indium (Sn-In) compound, a tin-indium-silver (Sn-In-Ag) compound, a tin-indium-copper (Sn-In-Cu) compound, a tin-indium-silver-bismuth (Sn-In-Ag-Bi), or a tin-indium-silver-copper (Sn-In-Ag-Cu) compound.

According to various example embodiments, a semiconductor package includes a solder ball structure including a first solder ball having a first melting temperature and contacting a lower substrate pad on a lower surface of the package substrate, and a second solder ball having a second melting temperature lower than the first melting temperature and contacting at least a portion of a surface of the first solder ball. The semiconductor package may be mounted on a circuit board by melting the second solder ball included in the solder ball structure at a temperature lower than the first melting temperature. Therefore, a damage of the semiconductor package during the mounting process due to heat may be reduced.

In addition, because the mounting process may be performed at the temperature lower than the first melting temperature of the first solder ball, a warpage defect of the semiconductor chip and/or the package substrate may be reduced. Accordingly, a defect in which the semiconductor package and the circuit board are not bonded by the solder ball structure due to the warpage defect may be reduced.

However, the effects of the present inventive concepts are not limited to the above-mentioned effects, and may be variously expanded within a scope that does not depart from a spirit and a range of the present inventive concepts.

### BRIEF DESCRIPTION OF THE DRAWINGS

Various example embodiments will be more clearly understood from the following detailed description taken in conjunction with the accompanying drawings. FIGS. 1 to 15 represent various non-limiting, example embodiments as described herein.

FIGS. 1 and 2 are a cross-sectional view and a plan view illustrating a semiconductor packages, respectively, according to an example embodiment;

FIG. 3 is a cross-sectional view illustrating a semiconductor package according to an example embodiment;

FIGS. 4 to 9 are cross-sectional views and perspective views illustrating a method of manufacturing a semiconductor package according to an example embodiment;

FIG. 10 is a cross-sectional view illustrating a semiconductor module according to an example embodiment;

FIGS. 11 and 12 are cross-sectional views illustrating a method of manufacturing a semiconductor module according to an example embodiment;

FIGS. 13 and 14 are cross-sectional views illustrating a method for manufacturing a semiconductor module according to an example embodiment; and

FIG. 15 is a cross-sectional view illustrating a semiconductor module according to an example embodiment.

### DETAILED DESCRIPTION

Hereinafter, various example embodiments will be described in detail with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

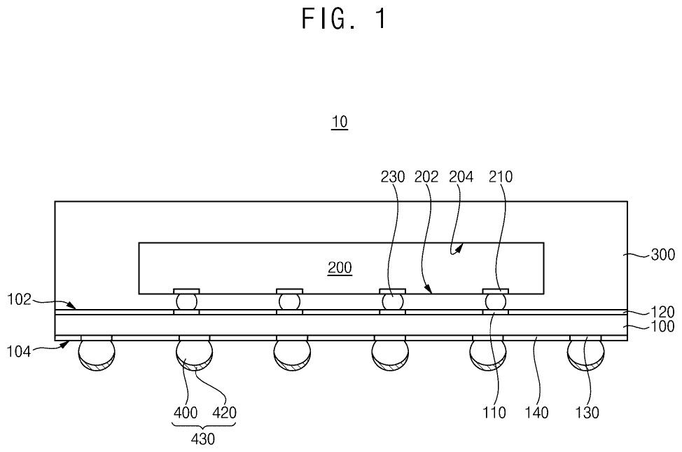

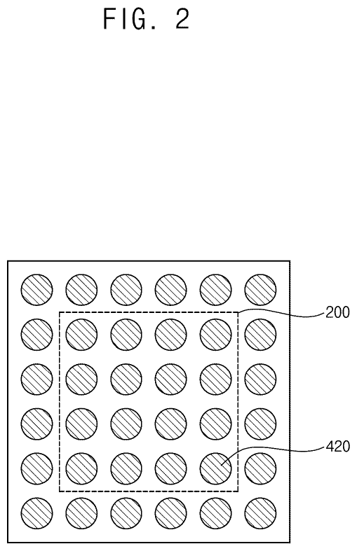

FIGS. 1 and 2 are a cross-sectional view and a plan view illustrating semiconductor packages, respectively, according to an example embodiment.

Referring to FIGS. 1 and 2, the semiconductor package 10 may include a package substrate 100, a semiconductor chip 200, a conductive bump 230, a molding member 300, and solder ball structures 430.

The package substrate 100 may have a first surface 102 and a second surface 104 facing each other. For example, the package substrate 100 may be a printed circuit board (PCB). The printed circuit board may have vias and various circuits therein. The package substrate 100 may be individualized by sawing a strip substrate including a plurality of package substrates.

The package substrate 100 may include a plurality of stacked insulation layers and wirings inside each of the insulation layers. In addition, the package substrate 100 may include a plurality of upper substrate pads 110 and a plurality of lower substrate pads 130. The wirings may include internal wirings as channels for electrical connection with different types of semiconductor chips.

The upper substrate pads 110 may be arranged on the first surface 102 of the package substrate 100, and upper surfaces of the upper substrate pads 110 may be exposed by the first surface 102 of the package substrate 100. An upper insulation layer 120 may be disposed between the upper substrate pads 110 on the first surface 102 of the package substrate 100.

The lower substrate pads 130 may be arranged on the second surface 104 of the package substrate 100, and lower surfaces of the lower substrate pads 130 may be exposed by the second surface 104 of the package substrate 100. The lower insulation layer 140 may be disposed between the lower substrate pads 130 on the second surface 104 of the package substrate 100. The lower substrate pads 130 may be provided to input and output electric signals.

In some example embodiments, the package substrate 100 may include a chip mounting area at a center portion (or a central portion) of the package substrate 100. The upper substrate pads 110 may be arranged in the chip mounting area of the package substrate 100. The upper substrate pads 110 may be arranged in an array form within the chip mounting area. In a plan view, the package substrate 100 may have a rectangular shape.

The semiconductor chip 200 may be mounted on an upper surface of the package substrate 100. A conductive bump 230 may be interposed between the semiconductor chip 200 and the upper surface of the package substrate 100. The semiconductor chip 200 may be mounted on the chip mounting area of the package substrate 100 via the conductive bumps 230. In a plan view, the semiconductor chip 200 may have a rectangular shape.

The semiconductor chip 200 may include a substrate including a semiconductor material. The semiconductor chip 200 may include a third surface 202 on which a circuit pattern and chip pads 210 are formed, and a fourth surface 204 opposite the third surface 202. The third surface 202 of the semiconductor chip 200 may be disposed to face the package substrate 100.

A semiconductor material may be exposed by the fourth surface 204 of the semiconductor chip 200. That is, the circuit pattern and chip pads may not be formed on the fourth surface 204 of the semiconductor chip 200. The fourth surface 204 of the semiconductor chip 200 may be substantially flat.

In some example embodiments, the semiconductor chip 200 may be mounted on the package substrate 100 by a flip chip bonding process. The chip pads 210 of the semiconductor chip 200 may be electrically connected to the upper substrate pads 110 of the package substrate 100 by the conductive bumps 230. A gap may be formed between the semiconductor chip 200 and the package substrate 100 by the conductive bumps 230.

For example, the conductive bumps 230 may include micro bumps (uBumps). Each of the conductive bumps 230 may include a conductive pillar as a lower bump and a solder as an upper bump.

The molding member 300 may be positioned on the package substrate 100 to cover the semiconductor chip 200. The molding member 300 may fill the gap between the package substrate 100 and the semiconductor chip 200, and may cover the upper surface (e.g., the first surface 102) of the package substrate 100 and a sidewall and an upper surface (e.g., the fourth surface 204) of the semiconductor chip 200. The molding member 300 may include an epoxy mold compound (EMC).

A structure of the semiconductor chip 200 mounted on the package substrate 100 may not be limited thereto. In some example embodiments, the package substrate 100 may have a stacked chip structure in which a plurality of semiconductor chips are stacked. For example, the semiconductor package 10 may include a semiconductor memory device having a 2.5D chip structure. In this case, the semiconductor chip 200 may include a logic semiconductor device or a memory device. The logic semiconductor device may be an ASIC as a host, such as a CPU, a GPU, or an SoC. The memory device may include a high bandwidth memory (HBM) device, a dynamic random access memory (DRAM), a flash memory device, etc. In some example embodiments, the semiconductor package 10 may include a semiconductor memory device having a 3D chip structure.

The solder ball structure 430 may be an external connection member for electrical connection with an external device. The solder ball structure 430 may be arranged on the lower substrate pad 130.

The semiconductor chip 200 may be electrically connected to the solder ball structures 430 by the conductive bump 230, the upper substrate pad 110, the wirings in the package substrate 100, and the lower substrate pad 130. Accordingly, the semiconductor chip 200 may be electrically connected to the external device via the solder ball structure 430.

The solder ball structure 430 may include a first solder ball 400 directly contacting the lower substrate pad 130 and a second solder ball 420 contacting and covering at least a portion of the surface of the first solder ball 400. The first solder ball 400 and the second solder ball 420 may be bonded to each other.

The second solder ball 420 may cover a second surface of the first solder ball 400, and the second surface may be opposite a first surface of the first solder ball 400 directly contacting the lower substrate pad 130. That is, the second solder ball 420 may be disposed at a portion being connected to the external device (e.g., a circuit board) in the solder ball structure 430.

The first solder ball 400 may have a first melting temperature, and the second solder ball 420 may have a second melting temperature lower than the first melting temperature. In some example embodiments, a difference between the first melting temperature and the second melting temperature may be at least 30° C.

The first melting temperature may be 190° C. or higher. In some example embodiments, the first melting temperature may be about 200° C. to about 250° C.

The first solder ball 400 may include a first solder material. The first solder material may be a compound including at least tin (Sn) and silver (Ag). The first solder material may not include bismuth (Bi) and indium (In).

The first solder material may include, for example, a tin-silver (Sn-Ag) compound, a tin-silver-copper (Sn-Ag-Cu) compound, a tin-silver-copper-nickel (Sn-Ag-Cu-Ni) compound, a tin-silver-copper-antimony (Sn-Ag-Cu-Sb) compound, or a tin-silver-copper-germanium (Sn-Ag-Cu-Ge) compound. For example, when the first solder material includes the tin-silver-copper (Sn-Ag-Cu) compound, the first solder ball 400 may have a melting temperature of about 217° C.

In some example embodiments, the second melting temperature may be about 130° C. to About 170° C.

The second solder ball 420 may include a second solder material. The second solder material may be a compound including tin (Sn) and at least one of bismuth (Bi) or indium (In). In some example embodiments, silver (Ag) and copper (Cu) may be added in a relatively small amount.

The second solder material may be a Sn-Bi based compound including at least tin (Sn) and bismuth (Bi) or a Sn-In based compound including at least tin (Sn) and indium (In). As amount of bismuth and/or indium increases, a melting temperature of the solder material is lowered. Therefore, the second solder ball having a target low melting temperature may be formed by controlling the amount of the bismuth and/or the indium.

For example, the Sn-Bi based compound used as the second solder material may include a tin-bismuth (Sn-Bi) compound, a tin-bismuth-silver (Sn-Bi-Ag) compound, a tin-bismuth-copper (Sn-Bi-Cu) compound, or a tin-bismuth-silver-copper (Sn-Bi-Ag-Cu) compound. For example, when the second solder material includes a tin-bismuth-silver (Sn-Bi-Ag) compound, the second solder ball may have a melting temperature of about 139° C.

For example, the Sn-In based compound used as the second solder material may include a tin-indium (Sn-In) compound, a tin-indium-silver (Sn-In-Ag) compound, a tin-indium-copper (Sn-In-Cu) compound, a tin-indium-silver-bismuth (Sn-In-Ag-Bi), or a tin-indium-silver-copper (Sn-In-Ag-Cu) compound. The melting temperature of the Sn-In based compound may have a temperature range of about 150° C. to about 200° C. In some example embodiments, the Sn-In based compound used as the second solder material may have a melting temperature of about 150° C. to about 170° C. by controlling the amount of the indium. In some example embodiments, the second solder ball 420 may include a first solder paste having the second melting temperature, and the first solder paste may be bonded onto the first solder ball 400.

The second solder ball 420 may have weaker brittleness than the first solder ball 400. Therefore, compared to a solder ball having only the second solder material, the solder ball structure 430 including the first solder ball 400 and the second solder ball 420 may have relatively high reliability (or improved reliability).

The second solder ball 420 may be a portion to be bonded to the circuit board, in the solder ball structure 430 of the semiconductor package 10.

A bonding portion of the solder ball structure 430 included in the semiconductor package 10 may be melted at a temperature lower than the melting temperature of the first solder ball 400, so that the solder ball structure 430 may be mounted on the circuit board through heat treatment of the temperature lower than the first melting temperature. Therefore, thermal damage applied to the semiconductor package 10 during the mounting process may be reduced.

In addition, in some example embodiments, the solder ball structure 430 included in the semiconductor package 10 may be mounted on the circuit board at the first melting temperature.

In the mounting process, warpage defects of the semiconductor chip 200 and/or the package substrate 100 may occur, due to a difference between coefficients of thermal expansion of the semiconductor chip 200 and the package substrate 100. However, when the semiconductor package 10 is bonded on the circuit board, the bonding may be performed at the temperature lower than the melting temperature of the first solder ball 400. Therefore, the warpage defects of the semiconductor chip 200 and/or the package substrate 100 may be decreased. Accordingly, the defect in which the semiconductor package 10 and the circuit board are not bonded by the solder ball structure 430 due to the warpage defects may be reduced.

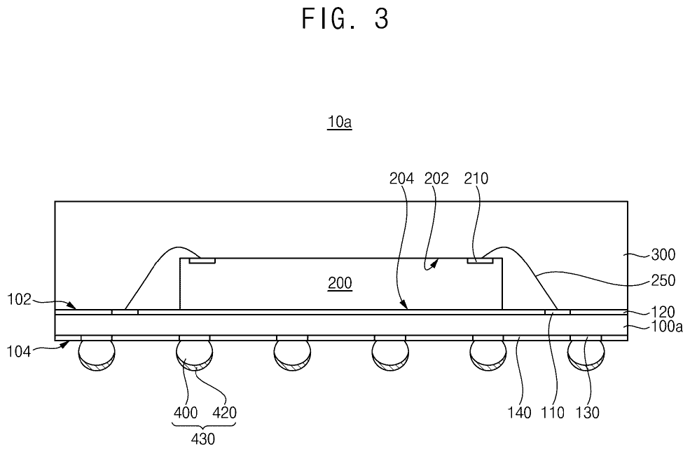

FIG. 3 is a cross-sectional view illustrating a semiconductor package according to an example embodiment.

The semiconductor package shown in FIG. 3 is substantially the same as the semiconductor package described with reference to FIGS. 1 and 2, except that the semiconductor chip and the package substrate are electrically connected by bonding wires.

Referring to FIG. 3, the semiconductor package 10a may include a package substrate 100a, a semiconductor chip 200, a bonding wire 250, a molding member 300, and solder ball structures 430.

Upper substrate pads 110 may be arranged on a first surface of the package substrate 100a, and lower substrate pads 130 may be arranged on a second surface of the package substrate 100a. In some example embodiments, the package substrate 100a may include a chip mounting area in a center portion (e.g., a central portion) of the package substrate 100a. The upper substrate pads 110 may be arranged outside the chip mounting area of the package substrate 100a.

The semiconductor chip 200 may be mounted on an upper surface of the package substrate 100a. The semiconductor chip 200 may include a third surface 202 on which a circuit pattern and chip pads 210 are formed, and a fourth surface 204 facing the third surface 202. The fourth surface 204 of the semiconductor chip 200 may be positioned so as to face the package substrate 100a. The third surface 202 of the semiconductor chip 200 may be positioned at upside.

The bonding wire 250 may connect the chip pads 210 of the semiconductor chip 200 and the upper substrate pads 110 of the package substrate 100a to each other.

The molding member 300 may be disposed on the package substrate 100a to cover the semiconductor chip 200.

The solder ball structure 430 may be disposed on the lower substrate pad 130. The solder ball structure 430 may include a first solder ball 400 directly contacting the lower substrate pad 130 and a second solder ball 420 covering at least a portion of a surface of the first solder ball 400. The solder ball structure 430 may be the same as that described with reference to FIGS. 1 and 2.

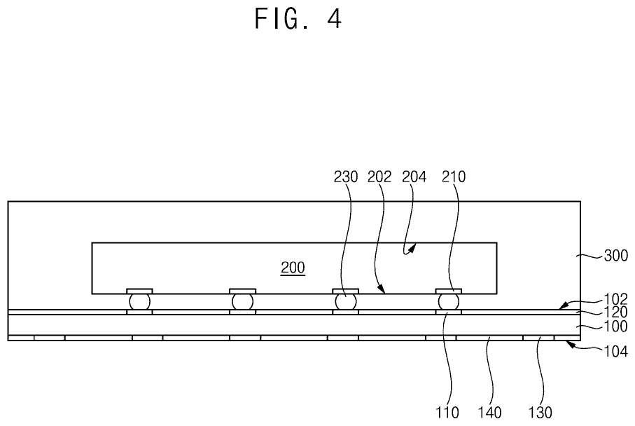

FIGS. 4 to 9 are cross-sectional views and perspective views illustrating a method of manufacturing a semiconductor package according to an example embodiment.

Referring to FIG. 4, a package substrate 100 may be provided. Upper substrate pads 110 may be arranged on the first surface 102 of the package substrate 100, and lower substrate pads 130 may be arranged on the second surface 104 of the package substrate 100. In some example embodiments, the lower substrate pads 130 formed on the second surface 104 of the package substrate 100 may be regularly arranged to have a constant interval.

A semiconductor chip 200 may be mounted on the package substrate 100.

In some example embodiments, a conductive bump 230 may be interposed between the semiconductor chip 200 and the first surface 102 of the package substrate 100, and the semiconductor chip 200 may be mounted on the package substrate 100 by the conductive bump 230. In this case, the semiconductor chip 200 and the package substrate 100 may be electrically connected to each other through the conductive bump 230.

In some example embodiments, the semiconductor chip 200 may be attached on the package substrate 100, and a bonding wire (not shown) may be formed between the semiconductor chip 200 and the first surface 102 of the package substrate 100. Accordingly, the semiconductor chip 200 and the package substrate 100 may be electrically connected to each other by the bonding wire. In this case, the semiconductor package shown in FIG. 3 may be manufactured through subsequent processes.

Hereinafter, a structure in which the conductive bump 230 is interposed between the semiconductor chip 200 and the first surface 102 of the package substrate 100 is described as an example.

For example, the semiconductor chip 200 may be mounted on the upper substrate pad 110 of or on the first surface 102 of the package substrate 100 by interposing the conductive bumps 230. The semiconductor chip 200 may be formed by performing device manufacturing processes on a substrate including a semiconductor material and a sawing process of the substrate. The semiconductor chip 200 may include a third surface 202 on which a circuit pattern and chip pads 210 are formed, and a fourth surface 204 facing the third surface 202.

The third surface 202 of the semiconductor chip 200 may be disposed to face the package substrate 100. In some example embodiments, the semiconductor chip 200 may be mounted on the package substrate 100 by a flip chip bonding process.

Thereafter, a molding member 300 covering the semiconductor chip 200 may be formed on the package substrate 100. The molding member 300 may include an epoxy mold compound (EMC).

In some example embodiments, the molding member 300 may completely cover the third surface 202 of the semiconductor chip 200.

In some example embodiments, although not shown, the molding member 300 may not cover the third surface 202 of the semiconductor chip 200. In this case, a metal capping layer (not shown) may be further included on the molding member 300 and the third surface 202 of the semiconductor chip 200.

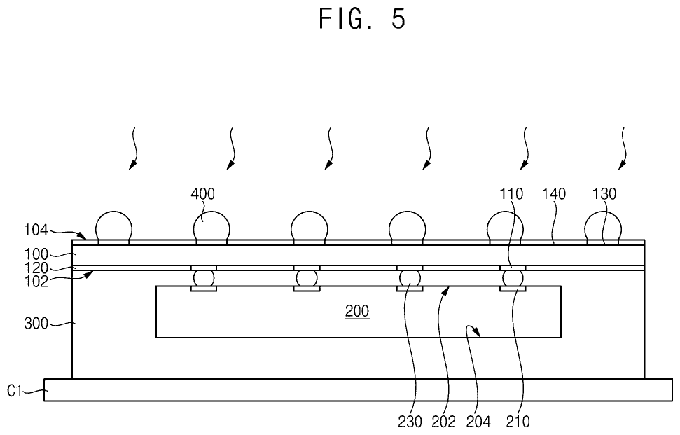

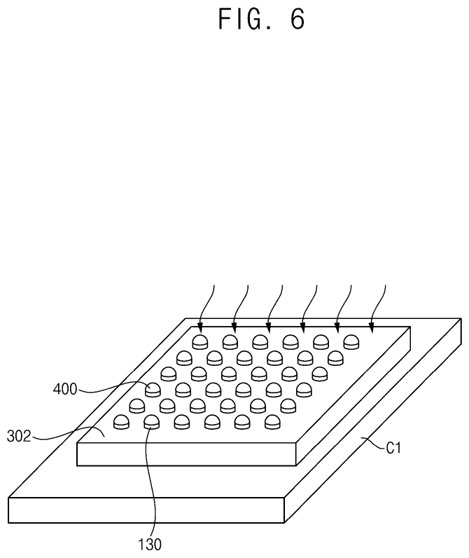

Referring to FIGS. 5 and 6, the package substrate 100 may be disposed on the carrier substrate C1 so that the second surface 104 of the package substrate 100 may face upward. Accordingly, the lower substrate pads 130 of the second surface 104 of the package substrate 100 may be exposed.

First solder balls 400 may be bonded on the lower substrate pads 130 of the second surface 104 of the package substrate 100, respectively. The first solder balls 400 may contact the lower substrate pads 130.

The first solder balls 400 may have a first melting temperature, and may include a first solder material. The first melting temperature may be 190° C. or higher. In some example embodiments, the first melting temperature may be about 200° C. to about 250° C. The first solder material may be a compound including at least tin (Sn) and silver (Ag). The first solder material may not include bismuth (Bi) and indium (In).

The first solder material may include, for example, a tin-silver (Sn-Ag) compound, a tin-silver-copper (Sn-Ag-Cu) compound, a tin-silver-copper-nickel (Sn-Ag-Cu-Ni) compound, a tin-silver-copper-antimony (Sn-Ag-Cu-Sb) compound, or a tin-silver-copper-germanium (Sn-Ag-Cu-Ge) compound. For example, when the first solder material includes a tin-silver-copper (Sn-Ag-Cu) compound, the first solder ball 400 may have a melting temperature of about 217° C.

In some example embodiments, in order to form the first solder ball 400, a first mask (not shown) may be formed on the second surface 104 of the package substrate 100. The first mask may have a plurality of first through-holes facing the lower substrate pads 130 on the second surface 104 of the package substrate 100. Accordingly, the lower substrate pads 130 may be exposed by the first through-holes, respectively.

The first solder balls 400 may pass through the first mask, and be placed on the lower substrate pads 130, respectively. Accordingly, the first solder balls 400 may be fixed on the lower substrate pads 130.

Thereafter, heat may be applied to the first solder balls 400 to melt the first solder balls 400. Accordingly, the first solder balls 400 may be bonded on the lower substrate pads 130, respectively. For example, the bonding process of the first solder balls 400 may be performed at a temperature of about 200° C. to about 250° C.

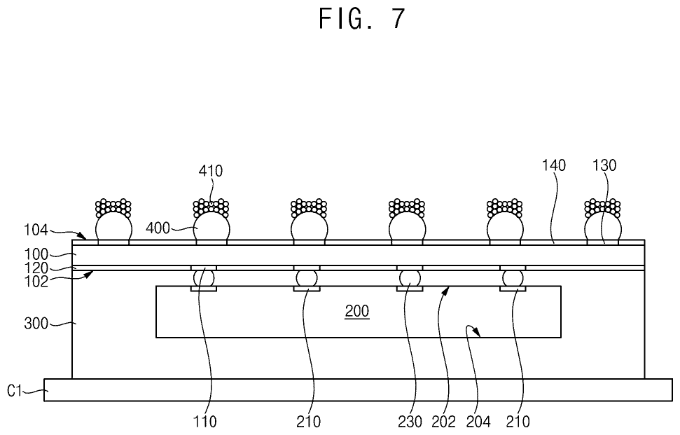

Referring to FIG. 7, the first solder paste 410 may be formed on the upper surface of the first solder ball 400 while the second surface 104 of the package substrate 100 is positioned so that the second surface 104 of the package substrate 100 faces upward. The first solder paste 410 may cover the upper surface of the first solder ball 400, and the first solder paste 410 may not be formed on a portion other than the surface of the first solder ball 400.

The first solder paste 410 may have a second melting temperature lower than the first melting temperature. In some example embodiments, the first solder paste 410 may have the second melting temperature that is at least 30° C. lower than the first melting temperature. For example, the second melting temperature may be about 130° C. to about 170° C.

The first solder paste 410 may include a second solder material. The second solder material may be a compound including tin (Sn) and at least one of bismuth (Bi) or indium (In).

The second solder material may be a Sn-Bi based compound including at least tin (Sn) and bismuth (Bi) or a Sn-In based compound including at least tin (Sn) and indium (In). As amount of bismuth and/or indium increases, the melting temperature of the solder material may be lowered. Therefore, the second solder ball having a target low melting temperature may be formed by controlling the amount of bismuth and/or indium.

For example, the Sn-Bi based compound used as the second solder material may include a tin-bismuth (Sn-Bi) compound, a tin-bismuth-silver (Sn-Bi-Ag) compound, a tin-bismuth-copper (Sn-Bi-Cu) compound, or a tin-bismuth-silver-copper (Sn-Bi-Ag-Cu) compound. For example, the Sn-In based compound used as the second solder material may include a tin-indium (Sn-In) compound, a tin-indium-silver (Sn-In-Ag) compound, a tin-indium-copper (Sn-In-Cu) compound, a tin-indium-silver-bismuth (Sn-In-Ag-Bi), or a tin-indium-silver-copper (Sn-In-Ag-Cu) compound. The melting temperature of the Sn-In based compound may have a temperature range of about 150° C. to about 200° C. In some example embodiments, the Sn-In based compound used as the second solder material may have a melting temperature of about 150° C. to about 170° C. by controlling the amount of the indium.

In some example embodiments, the first solder paste 410 may be formed on the surface of the first solder ball 400 through a printing process, a dispensing process, a dipping process, or a plating process. For example, the first solder paste 410 may be formed on the first solder ball 400 by printing the second solder material using a screen printing apparatus. For example, the first solder paste 410 may be formed by uniformly dispensing the second solder material on the surface of the first solder ball 400 and then drying the second solder material. For example, the first solder paste 410 may be formed by filling the second solder material into a dipping apparatus including a dipping tray or a solder paste container, dipping the first solder ball into the dipping apparatus, and drying the second solder material. For example, the first solder paste 410 may be formed by electroplating or electroless plating.

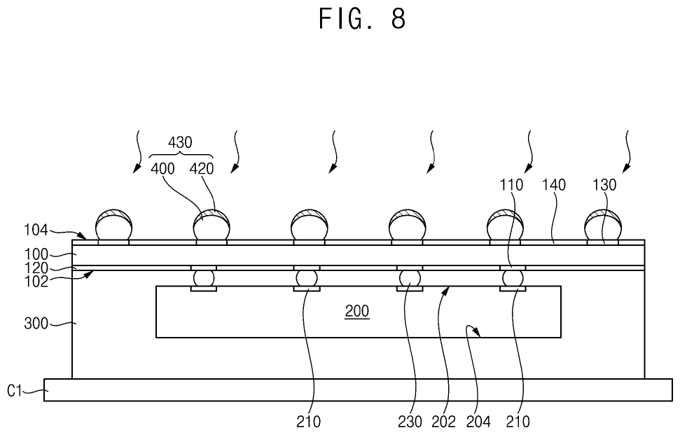

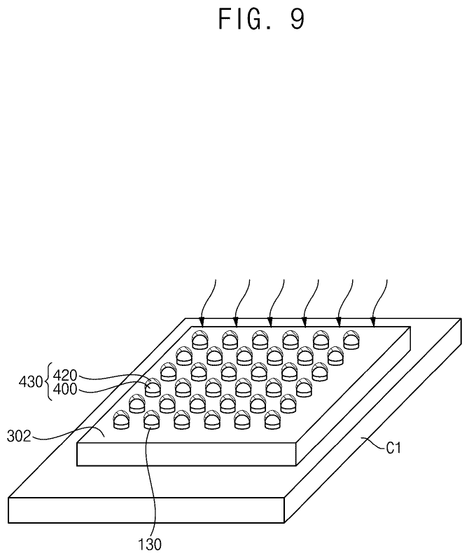

Referring to FIGS. 8 and 9, heat may be applied while the second surface 104 of the package substrate 100 is positioned so that the second surface 104 of the package substrate 100 faces upward. Selectively melting the first solder paste 410 formed on the surface of the first solder ball 400, so that a second solder ball 420 may be formed on the first solder ball 400. A heat treatment process may be performed at a temperature lower than the melting temperature of the first solder ball 400 so that the first solder ball 400 may not be melted. For example, the heat treatment process for forming the second solder ball 420 may be performed at a temperature of about 130° C. to about 170° C.

A solder ball structure 430 including the first solder ball 400 and the second solder ball 420 may be formed on the lower substrate pad 130 of the package substrate 100. The solder ball structure 430 may serve as one solder ball. After the solder ball structure 430 is formed, the carrier substrate C1 may be removed.

In a state where the second surface 104 of the package substrate 100 is positioned so that the second surface 104 of the package substrate 100 faces upward, the second solder ball 420 may cover the upper surface of the first solder ball 400.

The second solder ball 420 may be bonded on a second surface of the first solder ball 400, which is a portion facing a first surface of the first solder ball 400 attached to the surface of the lower substrate pad 130. The second solder ball 420 may cover the second surface of the first solder ball 400. Therefore, in the solder ball structure 430, the second surface of the first solder ball 400 may not be exposed.

When the heat treatment process for forming the solder ball structure 430 is performed, the bismuth and/or indium included in the first solder paste 410 may diffuse into an inner portion of the first solder ball 400, and thus contents of bismuth and/or indium in the first solder paste 410 may decrease. Therefore, the melting temperature of the first solder paste 410 may be increased. In some example embodiments, the first solder paste 410 and the first solder ball 400 may be merged into one material, such that the first and second solder balls 400, 420 may not be distinguished. In this case, a semiconductor package formed through subsequent processes may not have a low reflow temperature (e.g., a bonding temperature) for bonding the circuit board and the semiconductor package. Therefore, in the heat treatment process for forming the solder ball structure 430, the diffusion of bismuth and/or indium included in the first solder paste 410 into the first solder ball 400 may be desired to be suppressed. The heat treatment process for forming the solder ball structure 430 may be desired to be performed for a short period of time. In some example embodiments, the heat treatment process may be performed for 3 seconds to 10 seconds.

In the heat treatment process, the first solder ball 400 may be positioned facing upward. If the heat treatment process is performed while the first solder ball 400 is positioned facing downward, a portion of the first solder material included in the first solder ball 400 may easily diffuse into the second solder ball 420, and thus the melting temperature of the second solder ball 420 may be increased. Therefore, it may be difficult for the second solder ball 420 to have a target low melting temperature.

By the above processes, as shown in FIG. 1, the semiconductor package 10 including the package substrate 100, the semiconductor chip 200, the molding member 300, and the solder ball structure 430 may be manufactured. The solder ball structure 430 may include the first solder ball 400 and the second solder ball 420 having different melting temperatures.

In the solder ball structure 430 of the semiconductor package 10, the second solder ball 420 having the second melting temperature lower than the first melting temperature may correspond to a portion to be bonded to the circuit board. Therefore, the semiconductor package 10 may be mounted on the circuit board by a melting of the solder ball structure 430 at a temperature lower than the first melting temperature. Therefore, thermal damage applied to the semiconductor package 10 during the mounting process may be reduced.

In some example embodiments, if desired, the semiconductor package 10 may be mounted on the circuit board by melting the solder ball structure 430 at the first melting temperature.

Warpage of the semiconductor chip 200 and/or the package substrate 100 may occur during the mounting process due to a difference between coefficients of thermal expansion of the semiconductor chip 200 and the package substrate 100. However, the semiconductor package 10 may be bonded on the circuit board at the temperature lower than the first melting temperature of the first solder ball 400, so that the warpage of the semiconductor chip 200 and/or the package substrate 100 may be reduced. Accordingly, bonding defects between the semiconductor package 10 and the circuit board due to the warpage may be decreased.

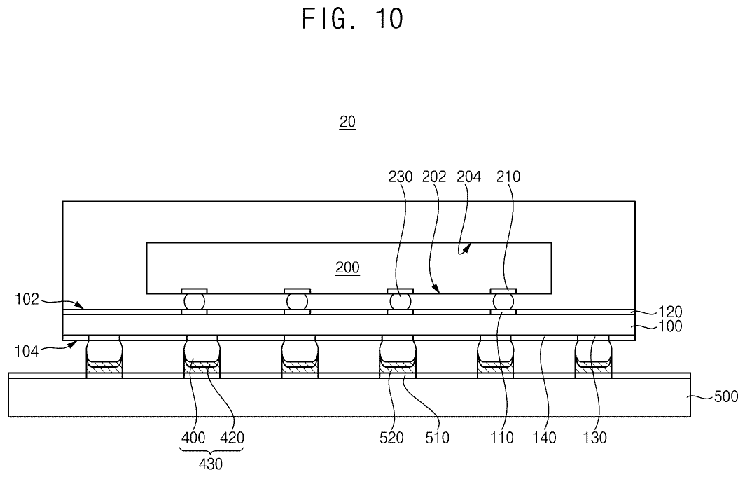

FIG. 10 is a cross-sectional view illustrating a semiconductor module according to an example embodiment.

Referring to FIG. 10, the semiconductor module 20 may include a circuit board 500 and a semiconductor package 10 on the circuit board 500.

The semiconductor package 10 may be as described with reference to FIGS. 1 and 2.

An upper pad pattern 510 may be arranged on an upper surface of the circuit board 500, and circuit wirings may be disposed within the circuit board 500.

A second solder paste 520 may be interposed between the upper pad pattern 510 of the circuit board 500 and the solder ball structure 430 of the semiconductor package 10, so that the circuit board 500 and the semiconductor package 10 may be bonded to each other.

The second solder paste 520 may have a third melting temperature lower than the first melting temperature of the first solder ball 400. In some example embodiments, the second solder paste 520 may have a melting temperature that is at least 30° C. lower than the first melting temperature. The third melting temperature may be about 130° C. to 170° C.

The second solder paste 520 may include a third solder material. The third solder material may be a compound including tin (Sn) and at least one of bismuth (Bi) or indium (In).

The third solder material may be a Sn-Bi based compound including at least tin (Sn) and bismuth (Bi) or a Sn-In based compound including at least tin (Sn) and indium (In). In some example embodiments, the third solder material may be the same as the second solder material.

Because the second solder ball 420 may be positioned at a soldering portion of the solder ball structure 430 in the semiconductor package 10, the circuit board 500 and the semiconductor package 10 may be bonded to each other using the second solder paste 520 (e.g., a low-temperature solder paste).

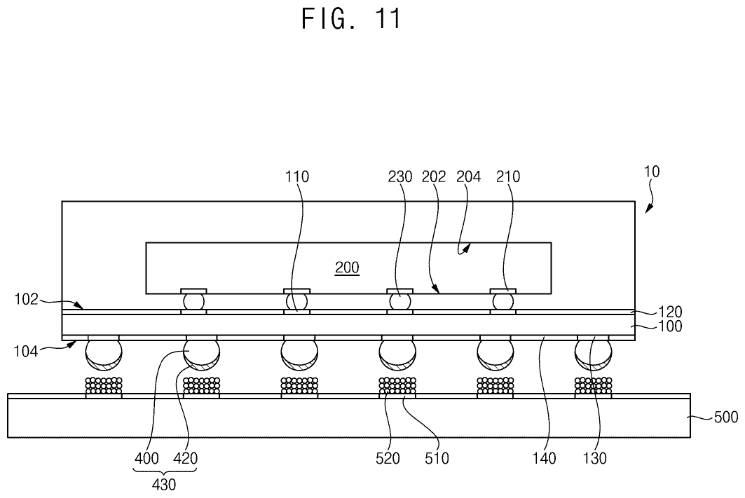

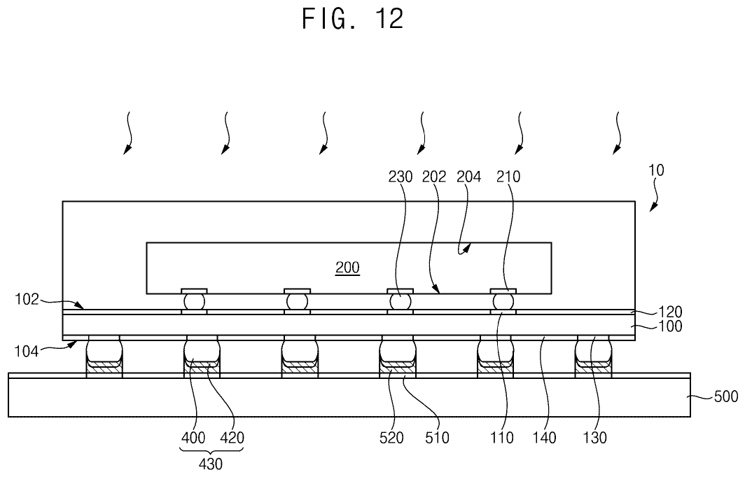

FIGS. 11 and 12 are cross-sectional views illustrating a method of manufacturing a semiconductor module according to an example embodiment.

Referring to FIG. 11, a circuit board 500 for mounting the semiconductor package 10 thereon may be provided. An upper pad pattern 510 may be arranged on an upper surface of the circuit board 500, and circuit wirings may be disposed within the circuit board 500.

A second solder paste 520 may be formed on the upper pad pattern 510 of the circuit board 500. The second solder paste 520 may have a third melting temperature lower than the first melting temperature of the first solder ball 400. In some example embodiments, the second solder paste 520 may have a melting temperature that is at least 30° C. lower than the first melting temperature. The third melting temperature may be about 130° C. to 170° C.

The second solder paste 520 may include a third solder material. The third solder material may be a compound including tin (Sn) and at least one of bismuth (Bi) or indium (In). The second solder material may be a Sn-Bi based compound including at least tin (Sn) and bismuth (Bi) or a Sn-In based compound including at least tin (Sn) and indium (In). In some example embodiments, the third solder material may be the same as the second solder material.

The circuit board 500 and the semiconductor package 10 may be disposed so as to contact the upper pad pattern 510 of the circuit board 500 and the solder ball structure 430 of the semiconductor package 10. In this case, the second solder paste 520 may contact the second solder ball 420 of the solder ball structure 430.

Referring to FIG. 12, heat may be applied while the second solder paste 520 and the second solder ball 420 of the solder ball structure 430 are in contact, so that the second solder paste 520 and the second solder ball 420 may be bonded to each other. Accordingly, the circuit board 500 and the semiconductor package 10 may be bonded to each other.

A heat treatment process may be performed so that the second solder paste 520 and the second solder ball 420 are selectively melted. In the heat treatment process, the first solder ball 400 may not be melted. For example, the heat treatment process for bonding the circuit board 500 and the semiconductor package 10 to each other may be performed at a temperature of about 130° C. to about 170° C.

As described above, the semiconductor package 10 and the circuit board 500 may be bonded at the temperature of about 130° C. to about 170° C. using the second solder paste 520 having a melting temperature of about 130° C. to about 170° C., and thus the semiconductor module 20 shown in FIG. 10 may be manufactured.

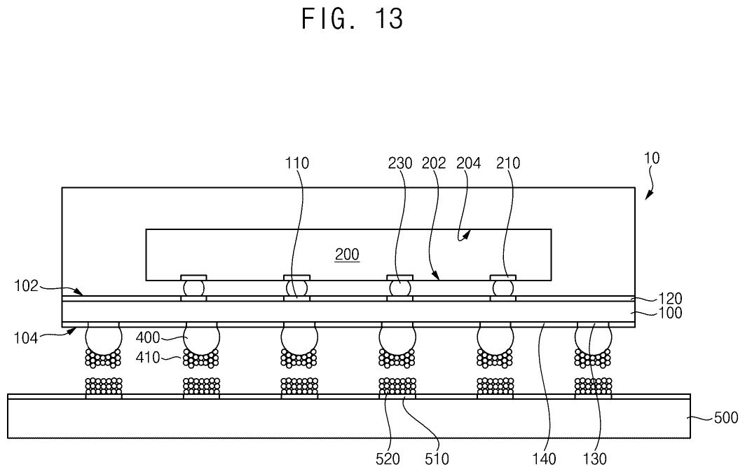

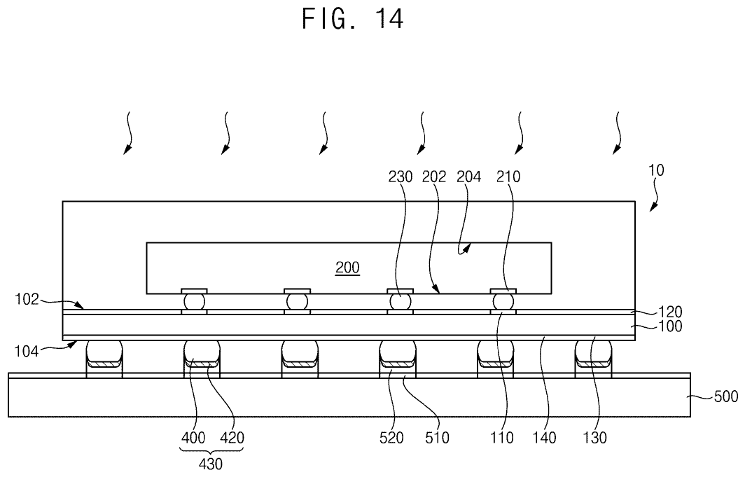

FIGS. 13 and 14 are cross-sectional views illustrating a method for manufacturing a semiconductor module according to an example embodiment.

Referring to FIG. 13, first, the processes described with reference to FIGS. 4 to 6 are performed.

Thereafter, the first solder paste 410 may be formed on a surface of a bonding portion of the first solder ball 400 in the package substrate 100.

The first solder paste 410 may have the second melting temperature lower than the first melting temperature of the first solder ball 400. In some example embodiments, the first solder paste 410 may have a second melting temperature that is at least 30° C. lower than the first melting temperature. For example, the second melting temperature may be about 130° C. to 170° C.

The first solder paste 410 may include a second solder material. The second solder material may be a compound including tin (Sn) and at least one of bismuth (Bi) or indium (In).

In some example embodiments, the second solder material may be a Sn-Bi based compound including at least tin (Sn) and bismuth (Bi) or a Sn-In based compound including at least tin (Sn) and indium (In).

For example, the Sn-Bi based compound used as the second solder material may include a tin-bismuth (Sn-Bi) compound, a tin-bismuth-silver (Sn-Bi-Ag) compound, a tin-bismuth-copper (Sn-Bi-Cu) compound, or a tin-bismuth-silver-copper (Sn-Bi-Ag-Cu) compound.

For example, the Sn-In based compound used as the second solder material may include a tin-indium (Sn-In) compound, a tin-indium-silver (Sn-In-Ag) compound, a tin-indium-copper (Sn-In-Cu) compound, a tin-indium-silver-bismuth (Sn-In-Ag-Bi), or a tin-indium-silver-copper (Sn-In-Ag-Cu) compound.

The circuit board 500 for mounting the semiconductor package 10 thereon may be provided. The upper pad pattern 510 may be arranged on an upper surface of the circuit board 500, and circuit wirings may be disposed within the circuit board 500.

The second solder paste 520 may be formed on the upper pad pattern 510 of the circuit board 500. The second solder paste 520 may have a third melting temperature lower than the first melting temperature. In some example embodiments, the second solder paste 520 may have a melting temperature that is at least 30° C. lower than the first melting temperature. The third melting temperature may be about 130° C. to 170° C.

The second solder paste 520 may include a third solder material. The third solder material may be a compound including tin (Sn) and at least one of bismuth (Bi) or indium (In).

The third solder material may be a Sn-Bi based compound including at least tin (Sn) and bismuth (Bi) or a Sn-In based compound including at least tin (Sn) and indium (In). In some example embodiments, the third solder material may be the same as the second solder material.

The circuit board 500 and the semiconductor package 10 may be disposed so that the upper pad pattern 510 of the circuit board 500 faces the first solder ball 400 of the semiconductor package 10. Accordingly, the second solder paste 520 on the circuit board 500 and the first solder paste 410 on the semiconductor package 10 may face each other.

Referring to FIG. 14, the second solder paste 520 and the first solder paste 410 may be brought into contact. Thereafter, heat may be applied while the second solder paste 520 and the first solder paste 410 contacts each other, and thus the second solder paste 520 and the first solder paste 410 may be bonded to each other. Accordingly, the circuit board 500 and the semiconductor package 10 may be bonded to each other.

In this case, the first and second solder pastes 410 and 520 may be melted. The first solder ball 400 may not be melted. For example, the heat treatment process for bonding the circuit board 500 and the semiconductor package 10 to each other may be performed at a temperature of 130° C. to 170° C.

As described above, the semiconductor module 20 may be manufactured by soldering at a temperature of 130° C. to 170° C. using the first and second solder pastes 520 having a melting temperature of 130° C. to 170° C.

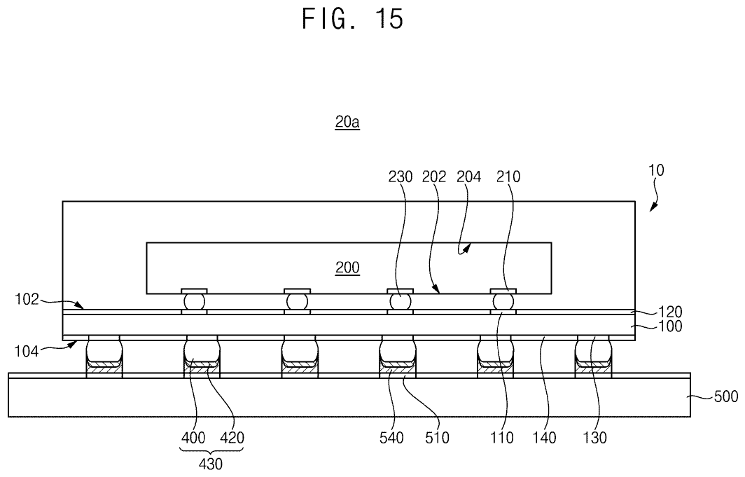

FIG. 15 is a cross-sectional view illustrating a semiconductor module 20a according to an example embodiment.

Referring to FIG. 15, the semiconductor module 20a may include a circuit board 500 and a semiconductor package 10 on the circuit board 500.

The semiconductor package 10 may be described with reference to FIGS. 1 and 2.

The upper pad pattern 510 may be arranged on the upper surface of the circuit board 500, and the circuit wirings may be arranged within the circuit board 500.

A third solder paste 540 may be interposed between the upper pad pattern 510 of the circuit board 500 and the solder ball structure 430 of the semiconductor package 10, so that the circuit board 500 and the semiconductor package 10 may be bonded to each other.

The third solder paste 540 may have a fourth melting temperature higher than the second melting temperature of the second solder ball 420. In some example embodiments, the third solder paste 540 may have a melting temperature the same as or lower the melting temperature of the first solder ball 400.

The third solder paste 540 may include a fourth solder material. The fourth solder material may have a melting temperature of 190° C. or higher. In some example embodiments, the fourth melting temperature may be about 200° C. to about 250° C. The fourth solder material may be a compound including at least tin (Sn) and silver (Ag). The fourth solder material may not include bismuth (Bi) and indium (In).

For example, the fourth solder material may include a tin-silver (Sn-Ag) compound, a tin-silver-copper (Sn-Ag-Cu) compound, a tin-silver-copper-nickel (Sn-Ag-Cu-Ni) compound, a tin-silver-copper-antimony (Sn-Ag-Cu-Sb) compound, or a tin-silver-copper-germanium (Sn-Ag-Cu-Ge) compound. In some example embodiments, the fourth solder material may be the same as the first solder material.

The semiconductor package 10 may include the solder ball structure 430. The circuit board 500 and the semiconductor package 10 may be bonded to each other using the third solder paste 540 (e.g., a high-temperature solder paste).

The semiconductor module 20a shown in FIG. 15 may be manufactured by the following processes.

The processes for manufacturing a semiconductor module 20a shown in FIG. 15 may be similar to the processes described with reference to FIGS. 11 and 12, except for a type of solder paste and the heat treatment process of the solder paste.

The circuit board 500 for mounting the semiconductor package 10 thereon may be provided. A third solder paste 540 may be formed on an upper pad pattern 510 of the circuit board 500.

The circuit board 500 and the semiconductor package 10 may be disposed so that the upper pad pattern 510 of the circuit board 500 and the solder ball structure 430 of the semiconductor package 10 contact each other. In this case, the third solder paste 540 may contact the second solder ball 420 of the solder ball structure 430.

Thereafter, heat may be applied while the third solder paste 540 and the second solder ball 420 of the solder ball structure 430 contacts to each other, so that the third solder paste 540 and the second solder ball 420 may be bonded to each other. In this case, the third solder paste 540 and at least the second solder ball 420 may be melted, so that the circuit board 500 and the semiconductor package 10 may be bonded to each other. In some example embodiments, in the heat treatment process, the first solder ball 400 may also be melted together.

For example, the heat treatment process for bonding the circuit board 500 and the semiconductor package 10 to each other may be performed at a temperature of about 200° C. to about 250° C.

As described above, the semiconductor module 20 shown in FIG. 13 may be manufactured by soldering at a temperature of about 200° C. to about 50° C. using the third solder paste 540 having a melting temperature of about 200° C. to about 250° C.

The semiconductor package described above may include a semiconductor device such as a logic device or a memory device. For example, the semiconductor package may include a logic device such as a central processing unit (CPU, MPU), an application processor (AP), etc., a volatile memory device such as an SRAM device, a DRAM device, etc., and a nonvolatile memory device such as a flash memory device, a PRAM device, an MRAM device, an RRAM device, etc.

According to an example embodiment, a method for manufacturing a semiconductor package includes mounting a semiconductor chip on a first surface of a package substrate, forming a molding member covering the semiconductor chip on the first surface of the package substrate, forming a first solder ball having a first melting temperature on a second surface of the package substrate that is opposite to the first surface of the package substrate, forming a first solder paste having a second melting temperature lower than the first melting temperature on a portion of a surface of the first solder ball, and selectively melting the first solder paste to form a second solder ball on the first solder ball, the second solder ball contacting at least a portion of a surface of the first solder ball.

In some example embodiments, selectively melting the first solder paste may be performed by a heat treatment process of the first solder paste at a temperature lower than the first melting temperature.

In some example embodiments, selectively melting the first solder paste may be performed for 3 seconds to 10 seconds.

In some example embodiments, selectively melting the first solder paste may be performed for 3 seconds to 10 seconds.

The foregoing is illustrative of various example embodiments and is not to be construed as limiting thereof. Although a few example embodiments have been described, those skilled in the art will readily appreciate that many modifications are possible in the example embodiments without materially departing from the novel teachings and advantages of the present inventive concepts.

What is claimed is:

1. A semiconductor package comprising:
a package substrate;
a semiconductor chip on a first surface of the package substrate;
a molding member on the first surface of the package substrate and covering the semiconductor chip; and
solder ball structures on a second surface of the package substrate, the second surface of the package substrate being opposite the first surface of the package substrate, each of the solder ball structures including a first solder ball and a second solder ball,
wherein the first solder ball has a first melting temperature and contacts a lower substrate pad on the second surface of the package substrate, and
wherein the second solder ball has a second melting temperature lower than the first melting temperature and contacts at least a portion of a surface of the first solder ball.

2. The semiconductor package of claim 1, wherein the first melting temperature is in range of 200° C. to 250° C., and the second melting temperature is in range of 130° C. to 170° C.

3. The semiconductor package of claim 1, wherein a difference between the first melting temperature and the second melting temperature is at least 30° C.

4. The semiconductor package of claim 1, wherein the first solder ball includes a compound including at least tin (Sn) and silver (Ag), and the first solder ball does not include bismuth (Bi) and indium (In).

5. The semiconductor package of claim 4, wherein the first solder ball includes a tin-silver (Sn-Ag) compound, a tin-silver-copper (Sn-Ag-Cu) compound, a tin-silver-copper-nickel (Sn-Ag-Cu-Ni) compound, a tin-silver-copper-antimony (Sn-Ag-Cu-Sb) compound, or a tin-silver-copper-germanium (Sn-Ag-Cu-Ge) compound.

6. The semiconductor package of claim 1, wherein the second solder ball includes a compound including tin (Sn) and at least one of bismuth (Bi) or indium (In).

7. The semiconductor package of claim 6, wherein the second solder ball includes a tin-bismuth (Sn-Bi) compound, a tin-bismuth-silver (Sn-Bi-Ag) compound, a tin-bismuth-copper (Sn-Bi-Cu) compound, a tin-bismuth-silver-copper (Sn-Bi-Ag-Cu) compound, a tin-indium (Sn-In) compound, a tin-indium-silver (Sn-In-Ag) compound, a tin-indium-copper (Sn-In-Cu) compound, a tin-indium-silver-bismuth (Sn-In-Ag-Bi) or a tin-indium-silver-copper (Sn-In-Ag-Cu) compound.

8. The semiconductor package of claim 1, wherein the first solder ball includes a third surface directly contacting the lower substrate pad and a fourth surface opposite the third surface, and wherein the second solder ball contacts the fourth surface of the first solder ball and covers the fourth surface of the first solder ball.

9. A semiconductor module, comprising:
a package substrate;
a semiconductor chip on a first surface of the package substrate;
a molding member on the first surface of the package substrate and covering the semiconductor chip;
a solder ball structure on a second surface of the package substrate, the second surface of the package substrate being opposite the first surface of the package substrate, the solder ball structure including a first solder ball and a second solder ball, the first solder ball having a first melting temperature and contacting a lower substrate pad on the second surface of the package substrate, the second solder ball having a second melting temperature lower than the first melting temperature, the second solder ball covering at least a portion of a surface of the first solder ball;
a circuit board including an upper pad pattern; and
a solder paste interposed between the upper pad pattern and the second solder ball of the solder ball structure and bonding the circuit board and the solder ball structure.

10. The semiconductor module of claim 9, wherein the first melting temperature is in range of 200° C. to 250° C., and the second melting temperature is in range of 130° C. to 170° C.

11. The semiconductor module of claim 9, wherein the first solder ball includes a compound including at least tin (Sn) and silver (Ag), and the first solder ball does not include bismuth (Bi) and indium (In).

12. The semiconductor module of claim 9, wherein the second solder ball is a compound including tin (Sn) and at least one of bismuth (Bi) or indium (In).

13. The semiconductor module of claim 9, wherein the solder paste has a melting temperature same as or lower than the first melting temperature of the first solder ball.

14. The semiconductor module of claim 9, wherein the solder paste has a melting temperature of 130° C. to 170° C.

15. The semiconductor module of claim 9, wherein the solder paste includes a compound including tin (Sn) and at least one of bismuth (Bi) or indium (In).

16. The semiconductor module of claim 15, wherein the solder paste includes a tin-bismuth (Sn-Bi) compound, a tin-bismuth-silver (Sn-Bi-Ag) compound, a tin-bismuth-copper (Sn-Bi-Cu) compound, a tin-bismuth-silver-copper (Sn-Bi-Ag-Cu) compound, a tin-indium (Sn-In) compound, a tin-indium-silver (Sn-In-Ag) compound, a tin-indium-copper (Sn-In-Cu) compound, a tin-indium-silver-bismuth (Sn-In-Ag-Bi) or a tin-indium-silver-copper (Sn-In-Ag-Cu) compound.

17. A semiconductor package comprising:
a package substrate;
a semiconductor chip on a first surface of the package substrate;
a molding member on the first surface of the package substrate and covering the semiconductor chip;
a first solder ball having a first melting temperature, the first solder ball being on a second surface of the package substrate, the second surface of the package substrate being opposite the first surface of the package substrate; and
a second solder ball bonded on at least a portion of a surface of the first solder ball, the second solder ball including a first solder paste, the second solder ball having a second melting temperature lower than the first melting temperature.

18. The semiconductor package of claim 17, wherein the first solder ball includes a third surface and a fourth surface, the third surface directly contacting a lower substrate pad on the second surface of the package substrate. the fourth surface opposite the third surface, and
wherein the second solder ball contacts the fourth surface of the first solder ball and covers the fourth surface of the first solder ball.

19. The semiconductor package of claim 17, further comprising:
a circuit board including an upper pad pattern; and
a second solder paste interposed between the upper pad pattern and the second solder ball and bonding the circuit board and the second solder ball.

20. The semiconductor package of claim 19, wherein the second solder paste has a melting temperature same as or lower than the first melting temperature of the first solder ball.
